(19) United States
(12) Patent Application Publication
(10) Pub. No.: US 2014/0165910 A1
(43) Pub. Date: Jun. 19, 2014

(54) APPARATUS FOR LARGE-AREA ATOMIC LAYER DEPOSITION

(71) Applicant: NCD CO., LTD., Daejeon (KR)

(72) Inventors: Woong Chul SHIN, Daejeon (KR); Kyu-Jeong CHOI, Daejeon (KR); Min BAEK, Daejeon (KR); Nak-Jin SEONG, Gyeryong-si (KR)

(73) Assignee: NCD CO., LTD., Daejeon (KR)

(21) Appl. No.: 14/163,056

(22) Filed: Jan. 24, 2014

(30) Foreign Application Priority Data
Nov. 29, 2012 (KR) 10-2012-0137349

(51) Int. Cl. H01L 31/18

(52) U.S. Cl. CPC H01L 31/18
USPC 118/719; 118/729; 118/724

(57) ABSTRACT

Disclosed is an apparatus for batch-type large-area atomic layer deposition, which can perform an atomic layer deposition process on a plurality of large-area glass substrates. The apparatus comprises: a vacuum chamber; gate valves provided at both sides of the vacuum chamber; a process gas supply unit provided in the upper portion of the vacuum chamber and configured to inject laminar-flow process gas downward; a gas discharge unit provided in the lower portion of the vacuum chamber and configured to discharge gas from the vacuum chamber; a cassette configured to load a plurality of substrates and disposed between the process gas supply unit and the gas discharge unit; and an elevating unit provided at the side of the gas discharge unit in the vacuum chamber and configured in the vacuum chamber to elevate the cassette so as to bring the cassette into close contact with the process gas supply unit.

### BACKGROUND OF THE INVENTION

1. Field of the Invention

The present invention relates to an apparatus for large-area atomic layer deposition, and more particularly to an apparatus for batch-type large-area atomic layer deposition, which can perform an atomic layer deposition process on a plurality of large-area glass substrates.

2. Description of the Prior Art

Recently, technologies of renewable energy sources such as sunlight and wind, which can be used as alternatives to fossil energy resources, have been developed. Particularly, in the solar photovoltaic power generation field, crystalline solar cells comprising solar cells formed on silicon substrates have been mainly used, and under such circumstances, thin film-type solar cells comprising solar cells formed on large-area glass substrates have been continuously developed.

Particularly, thin film-type solar cells have recently been significantly improved in terms of efficiency, can be made of large-area glass substrates at low costs, and can be installed on the outer wall of buildings. Due to these advantages, the thin film-type solar cells are receiving increasing attention. In the process of fabricating such thin film-type solar cells, deposition of atomic layers on large-area glass substrates is necessarily performed.

However, an atomic layer deposition apparatus capable of forming uniform thin films on large-area glass substrates within a short time has not yet been developed.

### SUMMARY OF THE INVENTION

Accordingly, it is an object of the present invention to provide an apparatus for large-area atomic layer deposition, which can perform an atomic layer deposition process of forming a uniform thin film on a plurality of large-area glass substrates.

To achieve the above object, the present invention provides an apparatus for batch-type large-area atomic layer deposition, the apparatus comprising: a vacuum chamber capable of forming a vacuum therein; gate valves provided at both sides of the vacuum chamber; a process gas supply unit provided in the upper portion of the vacuum chamber and configured to inject laminar-flow process gas downward; a gas discharge unit provided in the lower portion of the vacuum chamber and configured to discharge gas from the vacuum chamber; a cassette configured to load a plurality of substrates in a vertical position and disposed between the process gas supply unit and the gas discharge unit to form an internal chamber in which an atomic layer deposition process is to be performed; and an elevating unit provided at the side of the gas discharge unit in the vacuum chamber and configured to raise the cassette in the vacuum chamber so as to bring the cassette into close contact with the process gas supply unit.

In the present invention, the cassette is preferably open at the top and bottom thereof.

The cassette preferably has substrate-mounting slits in which a plurality of substrates are mounted in a predetermined distance from each other in a state in which they are inclined.

The substrate-mounting slit preferably comprises a side-supporting portion, which is provided in the top of the cassette and configured to one side of the inclined substrate, and a bottom-supporting portion which is provided at the bottom of the cassette and configured to support a portion of the bottom of the substrate.

The process gas supply unit preferably comprises: a process gas inlet portion configured to introduce process gas into the vacuum chamber from a process gas supply source provided outside the vacuum chamber; a process gas diffusion portion configured to diffuse the process gas introduced through the process gas inlet portion; and a buffer space forming portion provided under the process gas diffusion portion and configured to form a buffer space between the process gas diffusion portion and the top of the cassette.

The process gas diffusion portion and the buffer space forming portion are formed of a plurality of blocks.

The gas discharge unit preferably comprises: a discharge pump configured to discharge gas from the vacuum chamber to the outside; and a lower buffer space forming portion configured to form a lower buffer space between the discharge pump and the cassette.

The apparatus for large-area atomic layer deposition preferably further comprises a heating unit at the side of the vacuum chamber.

The apparatus for large-area atomic layer deposition preferably further comprises: a loading chamber provided at one side of the vacuum chamber and configured to introduce a cassette, which has loaded therein a plurality of substrates to be processed, into the vacuum chamber through the gate valve; an unloading chamber provided at the other side of the vacuum chamber and configured to receive a cassette, which has loaded therein a plurality of processed substrates, from the vacuum chamber through the gate valve; and a cassette return unit configured to connect the unloading chamber to the loading chamber and transfer the cassette from the unloading chamber to the side of the loading chamber.

The loading chamber preferably further comprises a substrate heating unit configured to heat the plurality of substrates to a predetermined temperature or higher.

### BRIEF DESCRIPTION OF THE DRAWINGS

FIG. 1 shows a layout of an apparatus for large-area atomic layer deposition according to an embodiment of the present invention.

FIG. 2 shows the internal structure of a vacuum chamber according to an embodiment of the present invention.

FIG. 3 shows the structure of a cassette according to an embodiment of the present invention.

FIG. 4 is a partial sectional view of a cassette according to an embodiment of the present invention.

FIG. 5 is a sectional view showing the structure of a process gas supply unit according to an embodiment of the present invention.

FIG. 6 shows the block structure of a process gas supply unit according to an embodiment of the present invention.

### DETAILED DESCRIPTION OF THE INVENTION

Hereinafter, preferred embodiments of the present invention will be described in detail with reference to the accompanying drawings.

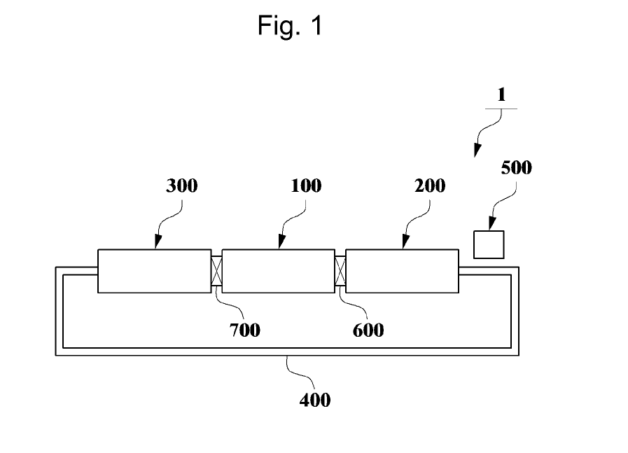

As shown in FIG. 1, an apparatus 1 for large-area atomic layer deposition according to an embodiment of the present invention comprises a vacuum chamber 100, a loading chamber 200, an unloading chamber 300 and a cassette return unit 400.

Herein, the vacuum chamber 100 is a chamber configured to perform an atomic layer deposition process, and the loading chamber 200 is a chamber configured to introduce a cassette, which has loaded therein a plurality of substrates to be processed, into the vacuum chamber 100. Also, the unloading chamber 300 is a chamber configured to receive a cassette, which has loaded therein a plurality of processed substrates, from the vacuum chamber 100.

In the vacuum chamber 100, an atomic layer deposition process is performed in a vacuum atmosphere. The vacuum chamber 100 preferably maintained at a significantly high temperature in order to reduce the process time. Thus, while an atomic layer deposition process is performed in the vacuum chamber 100, the loading chamber 200 receives a cassette having loaded therein a plurality of substrates to be processed, gas from the loading chamber 200 is vented to reduce the internal pressure of the chamber, and substrates introduced into the loading chamber 200 are preheated. If the substrates are preheated as described above, the process time of the atomic layer deposition process that is performed in the vacuum chamber 100 can be shortened, and the effect of depositing a uniform thin film on a plurality of substrates can be obtained.

Thus, the loading chamber 200 preferably further includes a substrate heating unit (not shown) capable of uniformly heating the plurality of substrates loaded in the cassette.

As a cassette in the vacuum chamber 100 is discharged into the unloading chamber 300 in a state in which the pretreatment of substrates to be processed has been completed in the loading chamber 200, a cassette in the loading chamber 200 is introduced into the vacuum chamber 100 through a gate valve 600, and a subsequent atomic layer deposition process is performed.

Meanwhile, the unloading chamber 300 receives a cassette having processed substrates loaded therein from the vacuum chamber 100, and then in a state in which a gate valve 700 between the vacuum chamber 100 and the unloading chamber 300 is closed, the cassette received in the unloading chamber 300 and the substrates loaded in the cassette are cooled and gas is injected into the unloading chamber 300 to increase the internal pressure of the chamber to approximately atmospheric pressure. Then, the cassette is discharged from the unloading chamber 300.

The cassette discharged from the unloading chamber is transferred through the cassette return unit 400 to the side of the loading chamber 200, and the processed substrates in the transferred cassette are transferred to other processes by a substrate transfer robot provided at the side of the loading chamber 200, and substrates to be processed are loaded in the cassette.

In some cases, the substrate transfer robot 500 may also be provided at the side of the unloading chamber 300 so that it loads the processed substrates and the empty cassette is returned to the side of the loading chamber 200 through the cassette return unit 400.

Further, the vacuum chamber 100 comprises elements for performing the atomic layer deposition process. Hereinafter, these elements will be described in detail.

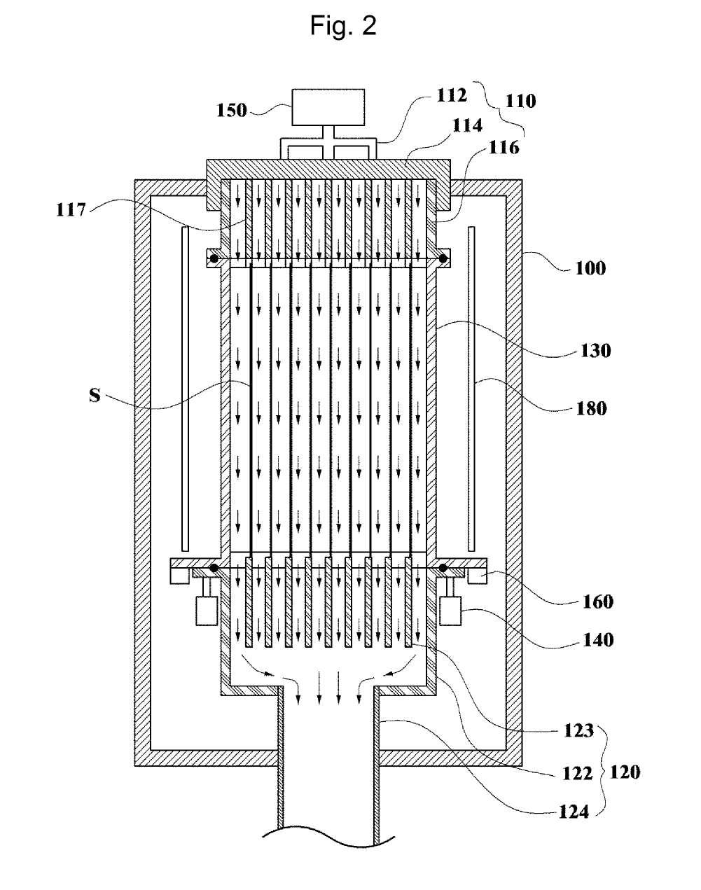

The vacuum chamber 100 is composed of a chamber capable of forming a vacuum therein. As shown in FIG. 2, the vacuum chamber 100 includes gate valves 600 and 700, a process gas supply unit 110, a gas discharge unit 120, a cassette 130, an elevating unit 140, and the like.

The gate valves 600 and 700 are provided between the vacuum chamber 100 and the loading chamber 200 and between the vacuum chamber 100 and the unloading chamber 300, respectively, and function to control a gate formed between the vacuum chamber 100 and the loading chamber 200 and a gate formed between the vacuum chamber 100 and the unloading chamber 300.

As shown in FIG. 2, the process gas supply unit 110 is provided at the top portion of the vacuum chamber 100 and functions to inject laminar-flow process gas downward. In this embodiment, the process gas supply unit 110 comprises a process gas inlet portion 112, a process gas diffusion portion 114 and a buffer space forming portion 116.

The process gas inlet portion 112 is configured to introduce process gas from a process gas supply source provided outside the vacuum chamber 100 into the vacuum chamber 100. Herein, the process gas can vary depending on a particular atomic layer deposition process to be performed. For example, when a ZrO₂ layer is to be deposited by an atomic layer deposition process, the gas supply source includes sources of Zr and O₃ as reactive gases and a source of N₂ as purge gas, and the process gas inlet portion 112 functions to introduce the reactive gases and the purge gas into the process gas diffusion portion 114. When these process gases are introduced, these gases may be controlled so as not to be mixed with each other and may be introduced into the process gas diffusion portion 114 through different pathways.

The process gas diffusion portion 114 functions to diffuse the process gas introduced from the process gas introduction portion 112. Specifically, it functions to sufficiently diffuse the process gas introduced into the vacuum chamber 110 from the process gas inlet portion 112 so that an atomic layer can be deposited on large-area glass substrates. In addition, it functions to inject the process gas so that the diffused process gas can move in the space between the substrates while maintaining laminar flow. For this purpose, as shown in FIG. 5, the process gas diffusion portion 114 comprises: a process gas diffusion plate 113 connected to the process gas inlet portion 112; and a plurality of injection holes formed through the process gas diffusion plate and configured to inject the process gas downward. Herein, as shown in FIG. 5, the plurality of injection holes 115 are formed at a predetermined distance from each other.

As shown in FIG. 5, the buffer space forming portion 116 is provided under the process gas diffusion portion 114 and configured to form a specific buffer space between the process gas diffusion portion 114 and the upper end of the cassette 130. As used herein, the term “buffer space” refers to a space having a diffusion width d2 that is wider than a width d1 in which the distribution space of process gas injected and diffused from one injection hole 115 overlaps with the distribution space of process gas injected and diffused from the adjacent injection hole 115 and that enables the process gas injected from the plurality of injection holes 115 to form uniform laminar flow. Thus, the vertical width of the buffer space forming portion 116 should be larger than the width d1 in which the process gases injected from adjacent injection holes 115 overlap with each other.

The laminar-flow process gas uniformly diffused by the buffer space forming portion 116 passes through the space between substrates S loaded in the cassette 130 and spaced at a predetermined distance from each other. Thus, as shown in FIG. 2, the buffer space forming portion 116 is divided by a plurality of division plates at the same distance as that between the substrates S loaded in the cassette 130. As shown in FIG. 2, the lower end of the division plates 117 is accurately aligned with the upper end of the substrates S mounted in the cassette 130 so that the space formed by the division of the buffer space forming space 116 communicates with the space formed between the substrates S. Thus, the process gas laminar flow formed by the buffer space forming portion 116 moves into the space between the substrates S to deposit an atomic layer on the surface of the substrates S.

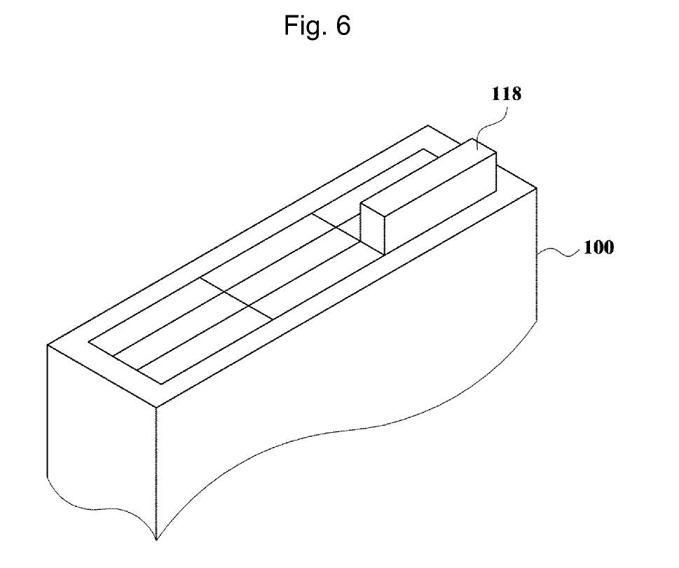

As shown in FIG. 6, in the apparatus 1 for large-area atomic layer deposition according to this embodiment, the process gas diffusion portion 114 and the buffer space forming portion 116 may be provided as an integral injection module consisting of a plurality of blocks 118. When the process gas supply unit 110 is composed of the plurality of injection module blocks 118, there is an advantage in that it is possible to process various sizes and numbers of substrates. Specifically, when the substrate size increases, the injection module blocks 118 will extend in the longitudinal direction, and when the number of substrates increases, the injection module blocks 118 will extend in the transverse direction.

As shown in FIG. 2, the gas discharge unit 120 is provided in the lower portion of the vacuum chamber 100 and configured to discharge gas from the inside of the vacuum chamber 100.

The process gas, supplied by the process gas supply unit 110 and passed through the space between the substrates S loaded in the cassette 130, is discharged from the vacuum chamber 100 through the gas discharge unit 120 to the outside. In this embodiment, the gas discharge unit 120 may comprise a discharge pump (not shown) and a lower buffer space forming portion 122. The discharge pump is configured to discharge gas from the vacuum chamber 110 to the outside, and one or more discharge pumps may be provided for the vacuum chamber 100. In addition, the discharge pump is connected to the vacuum chamber 110 through one or more outlet tubes 124.

Like the buffer space forming portion 116 as described above, the lower buffer space forming portion 122 provides a lower buffer space below the cassette 130 so that the laminar-flow process gas that passed through the space between the substrates S moves in the lower portion of the vacuum chamber while maintaining the laminar flow. Thus, like the buffer space forming portion 116, the lower buffer space forming portion 122 also have lower division plates 123 formed at the same distance as that between the substrates S. In addition, the upper end of the lower division plates 123 is accurately aligned with the lower end of the substrates S so that the laminar-flow process gas that passed through the substrates S passes through the space between the lower division plates while maintaining the laminar flow.

When the uniform laminar flow of the process gas is maintained even in the space below the substrates S by the lower buffer space forming portion 122, a uniform thin layer can be formed even on the lower end of large-area substrates.

In this embodiment, the cassette 130 has the optimum structure so that the atomic layer deposition process can be performed on a plurality of large-area substrates. Specifically, the cassette 130 is configured to load a plurality of substrates S in a vertical position and is disposed between the process gas supply unit 110 and the gas discharge unit 120 to provide an internal chamber in which the atomic layer deposition process is to be performed.

Thus, in this embodiment, the cassette 130 is open at the top and bottom thereof. The top of the cassette 130 is covered by the process gas supply unit 110, and the bottom is covered by the gas discharge unit 120. Thus, the inner chamber in which the atomic layer deposition process is to be performed is defined by the process gas supply unit 110, the gas discharge unit 120 and the side wall of the cassette 130.

In the apparatus 1 for large-area atomic layer deposition according to this embodiment, the process gas moves only in the inner chamber defined by the process gas supply unit 110, the gas discharge unit 120 and the side wall of the cassette 130, and the atomic layer deposition process can be quickly performed while continuously supplying the process gas.

In addition, as described above, the plurality of substrates S loaded in the cassette 130 are spaced from each other at the same distance as that between the division plates 117 of the buffer space forming portion 116.

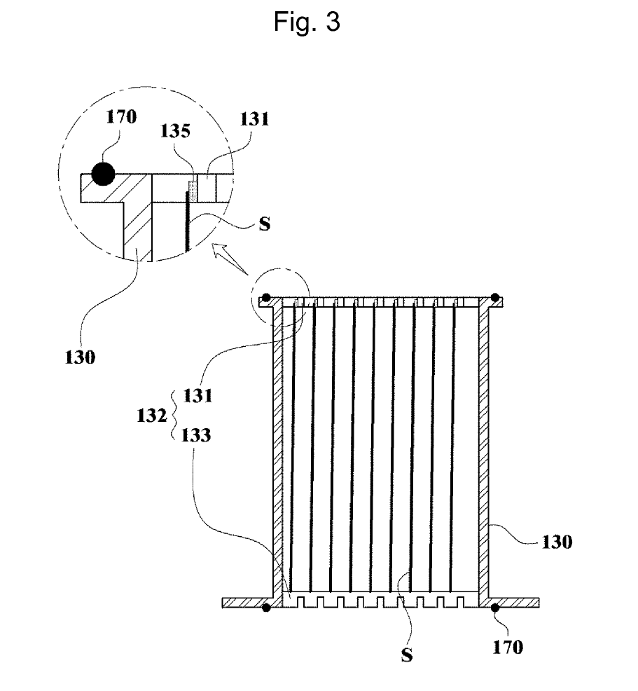

In order to maintain the plurality of substrates S at a constant distance, as shown in FIG. 3, the substrates S are preferably loaded such that they are spaced from each other at a constant distance in a state in which they are inclined in the same direction. Thus, the cassette 130 has substrate-mounting slits 132 so that the plurality of substrates S are mounted so as to be inclined in the same direction.

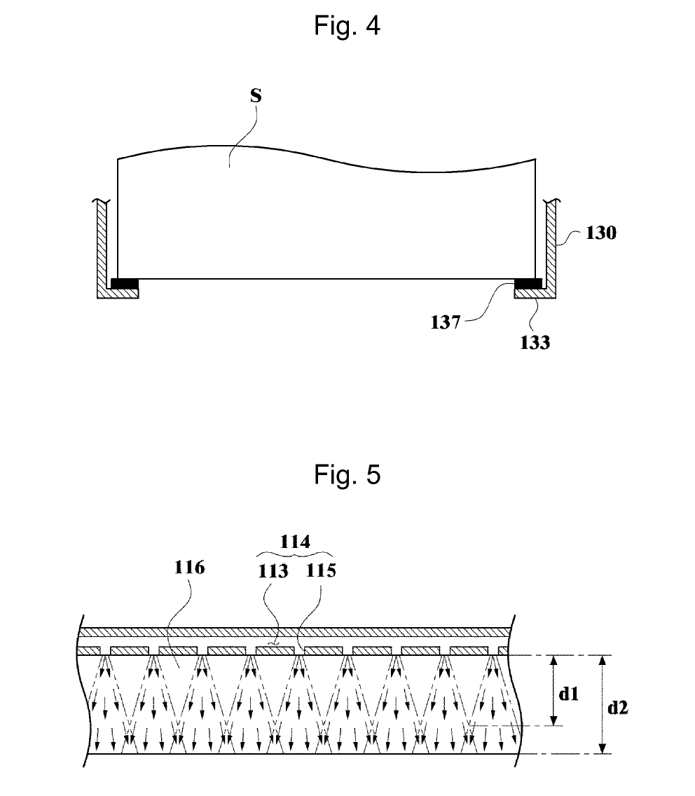

As shown in FIGS. 3 and 4, the substrate loading slit 132 may comprise a side-supporting portion 131, which is provided at the top of the cassette 130 and serves to support one side of the upper portion of the inclined substrate, and a bottom-supporting portion 133 which is provided at the bottom of the cassette 130 and serves to support a portion of the bottom of the substrate S. Herein, a portion of each of the side-supporting portion 131 and the bottom-supporting portion 133, which comes into direct contact with the substrate S, preferably has a damage preventing member 135 or 137. The damage preventing members 135 and 137 may be made of a material such as Teflon.

As shown in FIG. 2, the elevating unit 140 is disposed at the side of the gas discharge unit 120 in the vacuum chamber 100 and configured to elevate the cassette 130 in the vacuum chamber 100 so as to bring the cassette 130 into close contact with each of the glass discharge unit 120 and the process gas supply unit 110.

When the cassette 130 is to be introduced into the vacuum chamber 100 from the loading chamber 200, it is introduced while it is moved horizontally by rollers 160. Thus, in a state in which the cassette 130 is introduced into the vacuum chamber 100, the process gas supply unit 110 is spaced at a distance from the gas discharge portion 120. When the gas discharge portion 120 is moved upward by the elevating unit 140 in a state in which the horizontal movement of the cassette 130 to a predetermined position is completed, the gas discharge unit 120 is brought into close contact with the cassette 130, and when the gas discharge unit 120 is further moved upward, the top of the cassette 130 is brought into close contact with the process gas supply unit 110.

When this state is reached, the internal chamber in which the atomic layer deposition process is to be performed is completed. In order to prevent a gap from occurring between the cassette 130 and the gas discharge unit 120 and between the cassette and the process gas supply unit 110, a sealing member is preferably further provided.

Meanwhile, when the atomic layer deposition process is completed, the gas discharge unit 120 is moved downward according to the descending of the elevating unit 140 so that the cassette 130 is spaced from the process gas supply unit 110 and gas discharge unit 120. Then, the cassette 130 can move in the horizontal direction, and it is discharged from the unloading chamber 300.

Finally, a heating unit may further be provided at the side of the vacuum chamber 100. To perform the atomic layer deposition process, the substrates and the process should be heated to a predetermined temperature or higher. Thus, the heating unit 180 functions to heat the inside of the chamber 100 to a predetermined temperature or higher.

As described above, according to the present invention, a uniform thin film can be formed on the entire surface of a large-area substrate and can also be formed on a plurality of large-area substrates.

Particularly, a plurality of large-area substrates can be simultaneously subjected to an atomic layer deposition process, and thus the deposition process time required for a single substrate can be significantly reduced, thereby significantly increasing the production of thin film-type solar cells.

What is claimed is:

1. An apparatus for large-area atomic layer deposition, the apparatus comprising:
a vacuum chamber capable of forming a vacuum therein;
gate valves provided at both sides of the vacuum chamber;
a process gas supply unit provided in the upper portion of the vacuum chamber and configured to inject laminar-flow process gas downward;
a gas discharge unit provided in the lower portion of the vacuum chamber and configured to discharge gas from the vacuum chamber;
a cassette configured to load a plurality of substrates in a vertical position and disposed between the process gas supply unit and the gas discharge unit to form an internal chamber in which an atomic layer deposition process is to be performed; and
an elevating unit provided at the side of the gas discharge unit in the vacuum chamber and configured to elevate the cassette in the vacuum chamber so as to bring the cassette into close contact with the process gas supply unit.

2. The apparatus of claim 1, wherein the cassette open at the top and bottom thereof.

3. The apparatus of claim 2, wherein the cassette preferably has substrate-mounting slits in which a plurality of substrates are mounted in a predetermined distance from each other in a state in which they are inclined.

4. The apparatus of claim 3, wherein each of the substrate-mounting slits comprises a side-supporting portion, which is provided in the top of the cassette and configured to one side of the inclined substrate, and a bottom-supporting portion which is provided at the bottom of the cassette and configured to support a portion of the bottom of the substrate.

5. The apparatus of claim 1, wherein the process gas supply unit comprises:
a process gas inlet portion configured to introduce process gas into the vacuum chamber from a process gas supply source provided outside the vacuum chamber;
a process gas diffusion portion configured to diffuse the process gas introduced through the process gas inlet portion; and
a buffer space forming portion provided under the process gas diffusion portion and configured to form a buffer space between the process gas diffusion portion and the top of the cassette.

6. The apparatus of claim 5, wherein the process gas diffusion portion and the buffer space forming portion are formed of a plurality of blocks.

7. The apparatus of claim 1, wherein the gas discharge unit comprises:
a discharge pump configured to discharge gas from the vacuum chamber to the outside; and
a lower buffer space forming portion configured to form a lower buffer space between the discharge pump and the cassette.

8. The apparatus of claim 1, further comprising a heating unit at the side of the vacuum chamber.

9. The apparatus of claim 1, further comprising:
a loading chamber provided at one side of the vacuum chamber and configured to introduce a cassette, which has loaded therein a plurality of substrates to be processed, into the vacuum chamber through the gate valve;
an unloading chamber provided at the other side of the vacuum chamber and configured to receive a cassette, which has loaded therein a plurality of processed substrates, from the vacuum chamber through the gate valve; and
a cassette return unit configured to connect the unloading chamber to the loading chamber and transfer the cassette from the unloading chamber to the side of the loading chamber.

10. The apparatus of claim 9, wherein the loading chamber further comprises a substrate heating unit configured to heat the plurality of substrates to a predetermined temperature or higher.

11. The apparatus of claim 9, wherein the process gas diffusion portion is configured to diffuse different gases separately.
